(19) United States
(12) Patent Application Publication
(10) Pub. No.: US 2026/0244235 A1
(43) Pub. Date: Aug. 20, 2026

(54) VOLTAGE REFERENCE CIRCUIT

(71) Applicant: WISE-INTEGRATION, HYERES (FR)

(72) Inventors: Dominique BERGOGNE, SAINT-DIDIER-EN-VELAY (FR); Sebastian GAVIRIA DUQUE, GRENOBLE (FR); Plinio BAU, SAINT-MARTIN-D'HERES (FR)

(21) Appl. No.: 18/874,585

(22) PCT Filed: Jun. 19, 2023
(86) PCT No.: PCT/FR2023/050908

§ 371 Date: Dec. 13, 2024

(30) Foreign Application Priority Data
Jun. 23, 2022 (FR) 2206270

(51) Int. Cl. G05F 3/26; H10D 84/84

(52) U.S. Cl. CPC G05F 3/262; H10D 84/84

(57) ABSTRACT

A voltage reference circuit (1000) has a first branch (101) with a first depletion-mode top transistor (M1) connected to a voltage source (Vcc), a first enhancement-mode bottom transistor (M3) connected to the ground, and a dipole (D1) connected between the top transistor and the bottom transistor. A second branch (102) having a second depletion-mode top transistor (M4) is connected to a third depletion-mode transistor (M5), itself connected to a second enhancement-mode bottom transistor (M7) connected to the ground, the first top transistor being connected to the third depletion-mode transistor (M5), the first bottom transistor being connected to the second bottom transistor. The reference voltage (Vref) is provided to the source of the second top transistor.

### TECHNICAL FIELD

The invention relates to the field of voltage reference circuits used in integrated circuits.

The invention relates, in particular, to a voltage reference circuit having a more compact structure and making it possible to provide a constant voltage reference, even when the power source, the temperature or the parameters of the components vary.

### PRIOR ART

Conventionally, voltage reference circuits are circuits which provide a stable reference voltage which is constant over time. It is moreover sought to obtain a reference voltage which is not sensitive to variations of certain parameters.

As an example, these parameters are, for example, the power supply voltage, the temperature, the manufacturing dispersions or also the ageing of the components.

In particular, transistors are often found in voltage reference circuits. Yet, the parameters of a given transistor can greatly vary according to their manufacturing process. Moreover, two transistors resulting from the same manufacturing process can be widely different according to the positioning that they have on the semiconductor wafer having served their manufacture.

One of these parameters is the threshold voltage value from which a channel is formed between the drain and the source of a given transistor. This minimum value is that to be applied between the gate and the source, in order to drive an electric current between the drain and the source of said given transistor. This parameter can vary by up to 50% from one transistor to another, which can lead to a loss in stability of the voltage reference of the circuit.

A voltage reference circuit generally comprises two types of transistors: depletion-mode transistors and enhancement-mode transistors.

Such as illustrated in FIG. 1 of the prior art, a depletion-mode transistor 2005 is commonly symbolised with a solid line connecting the drain, the source and the base. An enhancement-mode transistor 2025 is commonly symbolised with a dotted line connecting the drain, the source and the base.

As an example, such as illustrated in FIG. 1 extracted from document U.S. Pat. No. 9,647.476 B2, a voltage reference circuit 2000 generally comprises a depletion-mode transistor 2005, the drain of which is connected to a voltage source V+, and the source of which is connected with eight enhancement-mode transistors 2025 in series. Each enhancement-mode transistor 2025 has its gate connected to its drain and the last enhancement-mode transistor of the series has its source connected to the ground. The gate of the depletion-mode transistor 2005 is also connected to the ground. The reference voltage Vref is measured between a point located between a capacitor 2015 and the source of an enhancement-mode transistor 2055, the gate of which is connected between the sixth and the seventh depletion-mode transistor of the series.

In this configuration, the voltage reference circuit 2000 makes it possible to obtain a low current consumption, typically less than 1 μA. However, such a circuit does not make it possible to reach high reference voltage values. Furthermore, this type of mounting is sensitive to variations in transistor parameters, and in particular, the reference voltage has instabilities.

According to another example, the publication, “A 23.6 ppm/° C. Monolithically Integrated GaN Reference Voltage Design with Temperature Range from −50° C. to 200° C. and Supply Voltage Range from 3.9 to 24V” by Cheng-Hsing Liao et al. describes several embodiments of voltage reference circuits.

FIG. 2 illustrates one of these embodiments, wherein the voltage reference circuit comprises a first branch including a depletion-mode transistor QD, the drain of which is connected to a voltage source VDD, the source of which is connected to a first terminal of a resistor R1, and the gate of which is connected to the second terminal of the resistor R1.

The second terminal of the resistor R1 is also connected to the drain of an enhancement-mode transistor QE2, the source of which is connected to the ground.

The voltage reference circuit of FIG. 2 also comprises a second branch including a first enhancement-mode transistor QE4, the drain of which is connected to the voltage source VDD, and the source of which is connected to a first terminal of a resistor R2.

The second terminal of the resistor R2 is connected to the drain of a second enhancement-mode transistor QE3, the gate of which is connected to its drain and the source of which is connected to the ground.

The first and second branches are interconnected, such that the gate of the depletion-mode transistor QD of the first branch is connected to the gate of the first enhancement-mode transistor QE4 of the second branch. In addition, the gate of the enhancement-mode transistor QE2 of the first branch and connected to the gate of the enhancement-mode transistor QE3 of the second branch, so as to form a current mirror.

The reference voltage Vref is taken at the source of the enhancement-mode transistor QE4.

FIG. 3 illustrates a second embodiment described in the publication by Cheng-Hsing Liao et al. mentioned above. The circuit has the same architecture as that described in FIG. 2. The circuit however comprises additional components. The first branch comprises an additional enhancement-mode transistor QE5, the drain of which is connected to the source of the enhancement-mode transistor QE2, and the source of which is connected to the ground.

The second branch comprises an additional resistor R2 connected between the resistor R2 and the drain of the enhancement-mode transistor QE2 and an additional enhancement-mode transistor QE6, the drain of which is connected to the source of the enhancement-mode transistor QE3, and the source of which is connected to the ground.

The gate of the transistor QE6 is connected, on the one hand, to the gate of the transistor QE5 and, on the other hand, to the drain of the transistor QE3.

FIG. 4 illustrates another voltage reference circuit described in the publication by Cheng-Hsing Liao et al. mentioned above, wherein the voltage reference circuit comprising a first branch including a first depletion-mode transistor QSG, D1, the drain of which is connected to a voltage source VDD, the source of which is connected to a first terminal of a first resistor RSG1, and the gate of which is connected to the second terminal of the first resistor RSG1. The first branch also includes a second depletion-mode transistor QSG, D3, the drain of which is connected to the second terminal of the first resistor RSG1, the source of which is connected to a first terminal of a second resistor RSG2, and the gate of which is connected to the second terminal of the resistor RSG2.

The drain of the second depletion-mode transistor QSG, D3 is also connected to the drain of an enhancement-mode transistor QSG, E1, the source of which is connected to the ground.

The circuit of FIG. 4 also includes a second branch comprising a first depletion-mode transistor QSG, D2, the drain of which is connected to the voltage source VDD. The first depletion-mode transistor QSG, D2 is connected, by its source, to the drain of a second depletion-mode transistor QSG, D4. The source of the second depletion-mode transistor QSG, D4 is connected to a first terminal of a third resistor RREF, the second terminal of which is connected to the drain of an enhancement-mode transistor QSG, E2. The source of the enhancement-mode transistor QSG, E2 is connected to the ground, while the gate of the enhancement-mode transistor QSG, E2 is connected to its drain.

The first and second branches are connected together at the depletion-mode transistors QSG, D1 and QSG, D2, the gates of which are connected. Likewise, the depletion-mode transistors QSG, D3 and QSG, D4 have their gates connected. Finally, the gates of the enhancement-mode transistors QSG, E1 and QSG, E2 are also connected together.

The reference voltage Vref is taken at the source of the depletion-mode transistor QSG, D4.

Although being stabler than the circuit of FIG. 1, the circuits described in FIGS. 2 to 4 comprise resistors R1, RSG1, RSG2 used to fix the current. This method is usually very effective, due to the linear behaviour of the resistor. However, to limit energy consumption, these resistors must be sufficiently large, which means that they also occupy a large semiconductor surface. Thus, it is difficult to incorporate such resistors in integrated circuits, moreover when it is sought to limit its surface as much as possible.

The problem that is proposed to resolve the invention is to obtain a stable voltage reference circuit, in particular regarding variations in method for manufacturing transistors, while limiting the consumption of the circuit, as well as the space that it occupies.

### SUMMARY OF THE INVENTION

To resolve this problem, the Applicant has developed a voltage reference circuit comprising:
a first branch comprising:
   a first depletion-mode top transistor, the drain of which is connected to a voltage source,
   a first enhancement-mode bottom transistor, the source of which is connected to the ground, the drain of which is connected, on the one hand, to the gate of the top transistor, and on the other hand, to the gate of said bottom transistor, and
   a dipole, a first terminal of which is connected to the source of the top transistor and the second terminal of which is connected to the drain of the first bottom transistor, and
a second branch comprising:
   a second depletion-mode top transistor, the drain of which is connected to the voltage source, the source of which is connected to the drain of a third depletion-mode transistor, and the gate of which is connected to the source of said third depletion-mode transistor, and
   a second enhancement-mode bottom transistor, the source of which is connected to the ground, and the drain of which is connected to the source of the third depletion-mode transistor,
      the source of the first top transistor of the first branch being connected to the gate of the third depletion-mode transistor of the second branch, the gates of the first bottom transistor of the first branch and of the second bottom transistor of the second branch being connected, so as to form a current mirror, the reference voltage being provided at the source of the second top transistor of the second branch.

Such a circuit has very few components compared with the circuit of the prior art of FIG. 1. Compared with the circuits of FIGS. 2 to 4, the circuit of the invention comprises substantially the same number of components and, in a variant, can advantageously comprise no resistor. It thus occupies a smaller surface compared with the prior art and is easier to integrate in circuits with reduced dimensions. In addition, less interference, linked to the interactions of the components together, appear on the voltage reference signal, due to the limited number of components. In addition to being more compact, the circuit of the invention has performances which are improved with respect to the circuits of the prior art, in particular regarding temperature stability.

According to a first embodiment, the dipole is an enhancement-mode transistor, the drain of which is connected, on the one hand, to the gate of said enhancement-mode transistor, and on the other hand, to the first terminal of the dipole, and the source of which is connected to the second terminal of the dipole.

A transistor, the gate of which is connected to its drain, almost behaves like a diode. The sizing of the transistor does not have, in principle, a significant impact on the value of the voltage reference. However, the sizing can be adapted in order to limit the energy consumption of the voltage reference circuit.

This embodiment is simpler. The circuit only comprises three depletion-mode transistors and four enhancement-mode transistors, that is seven components in total. Such a circuit is therefore particularly easy to implement in integrated circuits with reduced dimensions.

According to a second embodiment, the dipole comprises n enhancement-mode transistors, each of said enhancement-mode transistors having its gate connected to its drain, said enhancement-mode transistors being connected in series, two consecutive transistors being connected by the source of one and the drain of the other and, the drain of the first transistor forming the first terminal of the dipole and the source of the last transistor forming the second terminal of the second dipole.

The number of enhancement-mode transistors diode-mounted contained in the dipole is chosen so as to achieve a compromise between energy consumption and occupied surface. Indeed, the greater the number of enhancement-mode transistors diode-mounted, the lower the energy consumption of the circuit, but conversely, the circuit thus occupies more space.

According to a preferred embodiment, the dipole comprises three enhancement-mode transistors.

This embodiment represents an interesting compromise between energy consumption and occupied surface. In this embodiment, the voltage reference circuit comprises a ratio of the number of depletion-mode transistors to the number of enhancement-mode transistors substantially equal to two, which makes it possible to compensate for the variations in threshold value defined above. Indeed, for N-channel transistors, the depletion-mode transistors have a negative threshold value, while the depletion-mode transistors have a positive threshold value. Furthermore, the absolute value of the threshold value of an enhancement-mode transistor is substantially equal to double the threshold value of a depletion-mode transistor. Thus, an enhancement-mode transistor makes it possible to compensate for a pair of depletion-mode transistors. The threshold values are compensated for, even are cancelled, which makes it possible to limit the damaging effects on the value of the reference voltage.

In practice, the invention has a particularly advantageous application for transistors, for which there is no complementary transistor, i.e. when there is only one polarity, like the N-type in GaN, with the dual possibility of enhancement-mode and depletion-mode devices, such as GaN-type transistors, or NMOS transistors. However, the invention is also valid for complementary transistor technologies, like NPN or PNP bipolar transistors and N-or P-type CMOS transistors.

### DESCRIPTION OF THE FIGURES

The way in which to achieve the invention, as well as the advantages which arise from it, will emerge from the description of the embodiments below, in support of the accompanying figures, wherein:

FIG. 1 is a first electrical diagram of a voltage reference circuit of the prior art,

FIG. 2 is a second electrical diagram of a voltage reference circuit of the prior art,

FIG. 3 is a third electrical diagram of a voltage reference circuit of the prior art,

FIG. 4 is a fourth electrical diagram of a voltage reference circuit of the prior art,

FIG. 5 is an electrical diagram of the voltage reference circuit according to a first embodiment of the invention,

FIG. 6 is an electrical diagram of the voltage reference circuit according to a second embodiment of the invention,

FIG. 7 is an electrical diagram of the voltage reference circuit according to a third embodiment of the invention,

FIG. 8 is a comparative table of the performances of the reference circuits of the prior art of FIGS. 2 to 4 and of the circuit of the invention illustrated in FIG. 5.

FIG. 9 is a comparative graph of the development of the reference voltage according to the temperature of the circuit of the invention illustrated in FIG. 5 and for the circuit of the prior art of FIG. 4, and

FIG. 10 is a comparative graph of the development of the reference voltage according to the power supply voltage for theoretically identical transistors, but the intrinsic parameters of which differ, due to manufacturing tolerances, for the circuit of the invention illustrated in FIG. 5 and for the circuit of the prior art of FIG. 4.

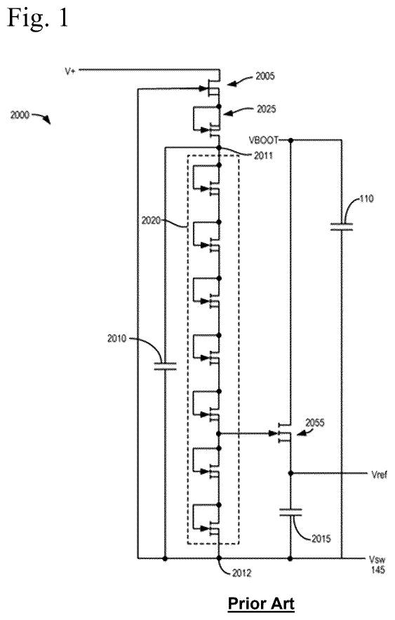

### DETAILED DESCRIPTION OF EMBODIMENTS

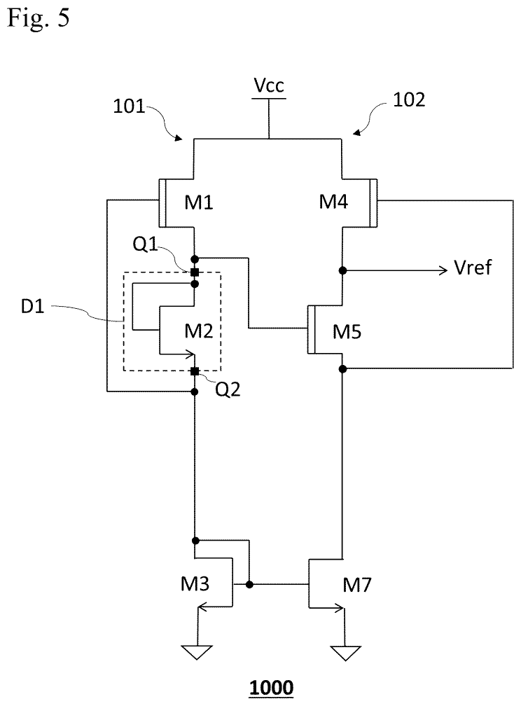

Such as illustrated in FIGS. 5 to 7, the voltage reference circuit of the invention comprises two branches 101, 102.

The first branch 101 comprises a first depletion-mode top transistor M1, the drain of which is connected to a voltage source Vcc. The voltage source Vcc preferably provides a direct voltage which could vary according to the current provided or according to time, and for example, of between 4 and 12V.

The first branch 101 also comprises a first enhancement-mode bottom transistor M3, the source of which is connected to the ground.

The two first top M1 and bottom M3 transistors are connected to one another by way of a dipole D1, D11, D21 advantageously having a resistive behaviour, linear or not. As an example, the dipole D1, D11, D21 is either a resistor, or a diode, or a diode-mounted transistor, comprising two terminals Q1, Q11, Q21 and Q2, Q12, Q22. The dipole D1, D11, D21 makes it possible to polarise the top transistor M1.

Thus, the first top transistor M1 is connected, by its source, to the first terminal Q1, Q11, Q21 of the dipole D1, D11, D21, while the first bottom transistor M3 is connected, by its drain, to the second terminal Q2, Q12, Q22 of the dipole D1, D11, D21.

Furthermore, the drain of the first bottom transistor M3 is also connected, on the one hand, to the gate of the first top transistor M1, and on the other hand, to its own gate.

In the embodiment of FIG. 5, the dipole D1 corresponds to an enhancement-mode transistor M2, diode-mounted, i.e. that its gate is connected to its drain. Thus, the drain of the enhancement-mode transistor M2 corresponds to the first terminal Q1 of the dipole D1 and the source of the enhancement-mode transistor M2 corresponds to the second terminal Q2 of the dipole D1.

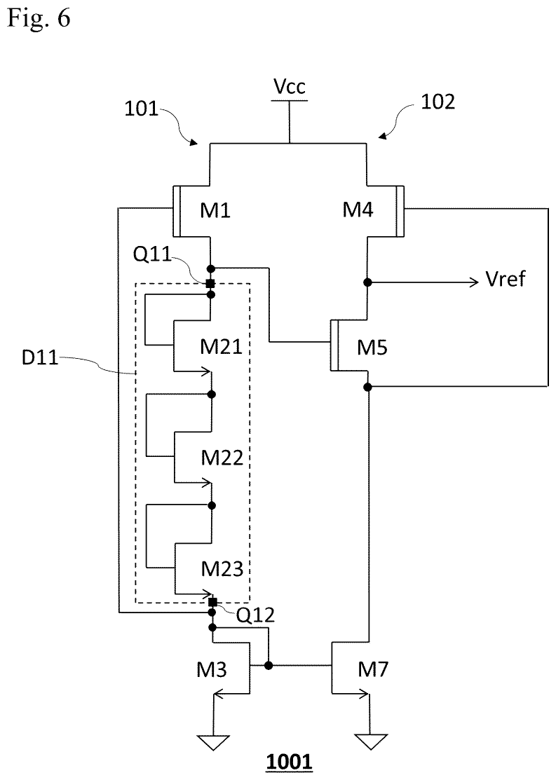

In the embodiment of FIG. 6, the dipole D11 corresponds to three enhancement-mode transistor M21, M22, M23 connected in series. The three transistors M21, M22, M23 are diode-mounted. Thus, the drain of the enhancement-mode transistor M21 corresponds to the first terminal Q11 of the dipole D11. The source of the enhancement-mode transistor M21 is connected to the drain of the enhancement-mode transistor M22 and the source of the enhancement-mode transistor M22 is connected to the drain of the enhancement-mode transistor M23. Finally, the source of the enhancement-mode transistor M23 corresponds to the second terminal Q12 of the dipole D11.

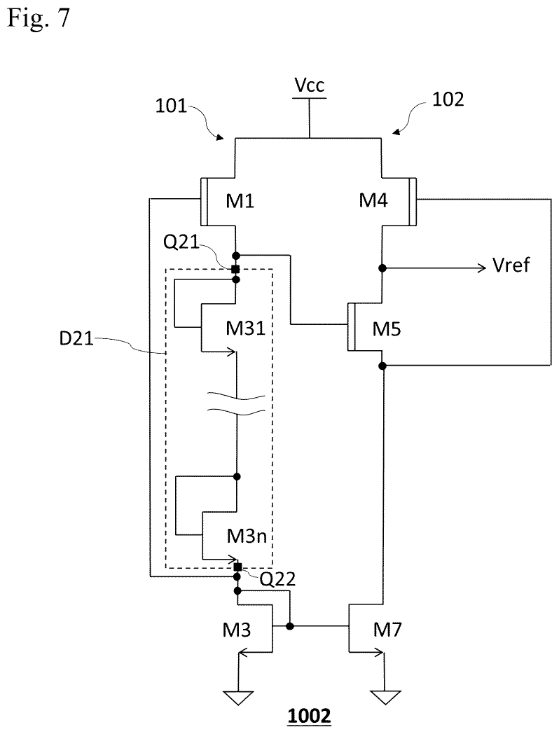

In the embodiment of FIG. 7, the dipole D21 corresponds to n enhancement-mode transistors M31-M3n connected in series. Each enhancement-mode transistor M31-M3n is diode-mounted. Thus, the drain of the enhancement-mode transistor M31 corresponds to the first terminal Q21 of the dipole D21 and the source of the enhancement-mode transistor M3n corresponds to the second terminal Q22 of the dipole D21. Two consecutive transistors are connected by the source of one and the drain of the other.

The second branch102 comprises a second depletion-mode top transistor M4, the drain of which is connected to the voltage source Vcc.

The second branch 102 also comprises a second depletion-mode bottom transistor M7, the source of which is connected to the ground.

The second top M4 and bottom M7 transistors are connected together by way of a third depletion-mode transistor M5.

Thus, the third depletion-mode transistor M5 is connected, by its drain, to the source of the second top transistor M4, and by its source, to the drain of the second bottom transistor M7.

The first and second branches 101, 102 are interconnected to two places.

Indeed, the source of the first top transistor M1, of the first branch 101 is connected to the gate of the third depletion-mode transistor M5 of the second branch 102.

Likewise, the gates of the first and second bottom transistors M3 and M7 are connected together, so as to form a current mirror. Thus, the current passing through the first bottom transistor M3 is copied in the second bottom transistor M7.

The voltage reference value Vref is measured at the source of the second top transistor M4 and with respect to the ground.

The transistors can belong to the category of GaN-type or MOS-type N transistors. These categories of transistors can have a negative threshold value, which makes it possible to compensate for the variations in manufacturing process, also called “corner”.

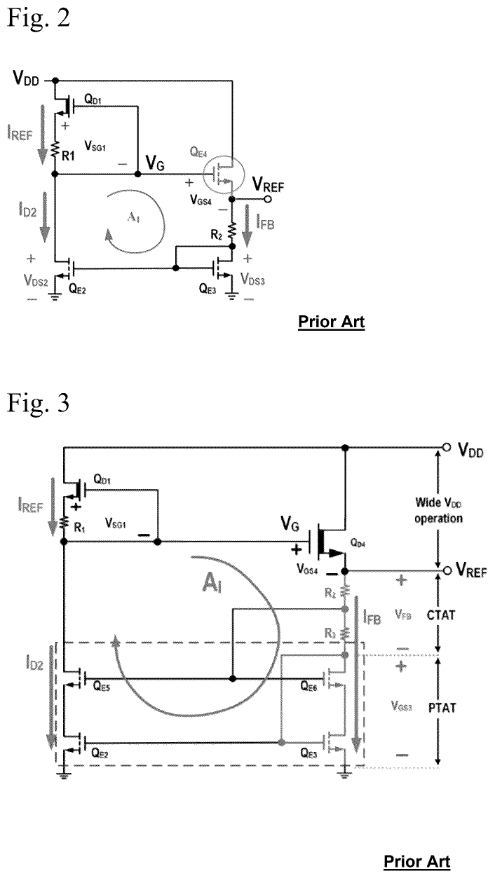

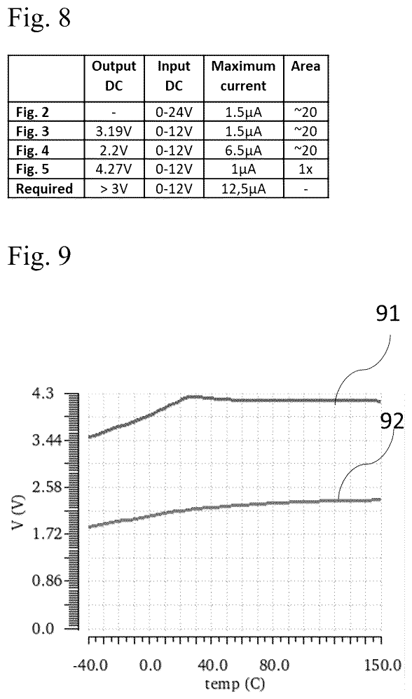

FIG. 8 illustrates a comparative table of performances of voltage reference circuits of FIGS. 2 to 4 and of the circuit of the invention of FIG. 5.

Thus, it is noted initially that the surface occupied by the circuits of the prior art is around 20 times greater than the surface occupied by the circuit of the invention. The circuit of the invention is therefore very compact, for comparable, even improved performances on certain points. Indeed, the circuit of the invention consumes a maximum current lower than the circuits of the prior art, typically equal to 1 μA.

Furthermore, the circuit of the invention has a lower variation regarding the temperature, compared with circuits of the prior art. Measurements have been taken by the Applicant in order to compare the performances obtained between the circuit of the invention and a circuit of the prior art.

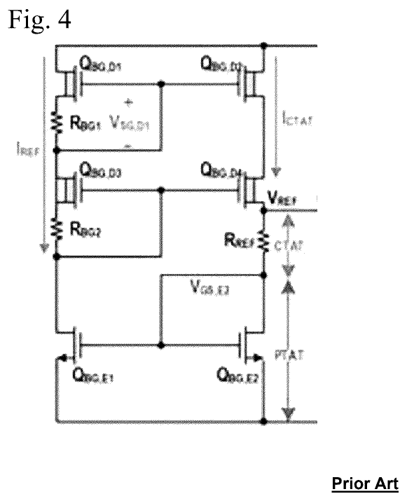

Such as illustrated in FIG. 9, between 25 and 150° C., the reference voltage of the invention 91 varies around 1%, while the reference voltage 92 of the circuit of the prior art of FIG. 4 varies by around 11.9%. The sensitivity to temperature of the circuit of the invention is therefore lowered by a factor 12 and the circuit is more robust.

The voltage reference circuit obtained is moreover not very sensitive to fluctuations in the power supply voltage, in the temperature and in variations of the method for manufacturing transistors.

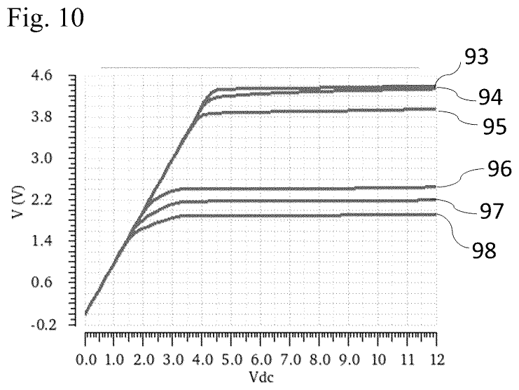

FIG. 10 compares the variations in reference voltage Vref for theoretically identical transistors, but the intrinsic parameters of which differ due to manufacturing tolerances.

For the circuit of the prior art 93-95 illustrated in FIG. 4, it is noted that for a power supply voltage greater than 4V, the reference voltage Vref measured for the transistors varies by 12.4%, while for the circuit of the invention 96-98 illustrated in FIG. 5, it varies by 5.4%, more than twice less.

To conclude, the invention makes it possible to obtain a stable voltage reference circuit, in particular regarding variations in method for manufacturing transistors and in temperature, while limiting the consumption of the circuit, as well as the space that it occupies.

1. A voltage reference circuit comprising:
a first branch comprising:
a first depletion-mode top transistor, the drain of which is connected to a voltage source,
a first enhancement-mode bottom transistor, the source of which is connected to the ground, the drain of which is connected, on the one hand, to the gate of the top transistor, and on the other hand, the gate of said bottom transistor, and
a dipole, a first terminal of which is connected to the source of the top transistor and the second terminal of which is connected to the drain of the first bottom transistor, and
a second branch comprising:
a second depletion-mode top transistor, the drain of which is connected to the voltage source, the source of which is connected to the drain of a third depletion-mode transistor, and the gate of which is connected to the source of said third depletion-mode transistor, and
a second enhancement-mode bottom transistor, the source of which is connected to the ground, and the drain of which is connected to the source of the third depletion-mode transistor,
the source of the first top transistor of the first branch being connected to the gate of the third depletion-mode transistor of the second branch, the gates of the first bottom transistor of the first branch and of the second bottom transistor of the second branch being connected so as to form a current mirror, the reference voltage being provided to the source of the second top transistor of the second branch.

2. The voltage reference circuit according to claim 1, wherein the dipole is a depletion-mode transistor, the drain of which is connected, on the one hand, to the gate of said enhancement-mode transistor (M2), and on the other hand, to the first terminal of the dipole, and the source of which is connected to the second terminal of the dipole.

3. The voltage reference circuit according to claim 1, wherein the dipole comprises n enhancement-mode transistors, each of said enhancement-mode transistors having its gate connected to its drain, said enhancement-mode transistors being connected in series, two consecutive transistors being connected by the source of one and the drain of the other and, the drain of the first transistor forming the first terminal of the dipole and the source of the last transistor forming the second terminal of the second dipole.

4. The voltage reference circuit according to claim 4, characterised in that the dipole (D11) comprises three enhancement-mode transistors (M21, M22, M23).

5. The voltage reference circuit according to claim 1, characterised in that the transistors are GaN transistors.
